(19) United States
(12) Patent Application Publication
(10) Pub. No.: US 2013/0180565 A1
(43) Pub. Date: Jul. 18, 2013

(54) SOLAR CELL, SOLAR CELL MODULE, AND METHOD FOR MANUFACTURING SOLAR CELL

(71) Applicant: Sanyo Electric Co. Ltd., Moriguchi City (JP)

(72) Inventor: Sasaki Manabu, Osaka City, Osaka (JP)

(73) Assignee: SANYO ELECTRIC CO., LTD., Moriguchi City (JP)

(21) Appl. No.: 13/721,515

(22) Filed: Dec. 20, 2012

Related U.S. Application Data
(63) Continuation of application No. PCT/JP2011/064549, filed on Jun. 24, 2011.

(30) Foreign Application Priority Data
Jun. 25, 2010 (JP) 2010-145429

(51) Int. Cl. H01L 31/028; H01L 31/18

(52) U.S. Cl. CPC H01L 31/028; H01L 31/1804
USPC 136/244; 136/261; 438/98

(57) ABSTRACT

A solar cell including a single crystal silicon substrate having electrical characteristic distribution, which is line-symmetric with respect to the center line in plan view, and in which portions equidistant from the center line have an electrical characteristic substantially uniform in an extending direction of the center line in the plan view, a semiconductor junction formed by using the single-crystal silicon substrate, and an electrode.

### CROSS REFERENCE TO RELATED APPLICATIONS

This application is a continuation application of International Application No. PCT/JP2011/064549, filed on Jun. 24, 2011, entitled “SOLAR CELL, SOLAR CELL MODULE, AND METHOD FOR MANUFACTURING SOLAR CELL”, which claims priority based on Article 8 of Patent Cooperation Treaty from prior Japanese Patent Applications No. 2010-145429, filed on Jun. 25, 2010, the entire contents of which are incorporated herein by reference.

### BACKGROUND OF THE INVENTION

1. Field of the Invention

This disclosure relates to a solar cell, a solar cell module, and a method for manufacturing the solar cell, and particularly relates to a solar cell and a solar cell module which include single-crystal silicon substrates and to a method for manufacturing the solar cell.

2. Description of Related Art

A solar cell including a single-crystal silicon substrate has been conventionally known. Generally, the single-crystal silicon substrate used in the solar cell is obtained in such a way that a columnar single-crystal silicon ingot whose height direction is a growth direction in growth of the ingot is sliced along planes orthogonal to the grown direction. A semiconductor junction, electrodes, and the like are formed in the single-crystal silicon substrate and the solar cell is thus formed.

Moreover, the single-crystal silicon ingot is generally formed by Czochralski method or the like. The ingot formed by Czochralski method is known to have concentrically-symmetric defect distribution due to the manufacturing method thereof. This is disclosed in Fumio Shimura, “Semiconductor Silicon Crystal Technology”, Maruzen Publishing Co., Ltd published on September 30, Heisei 5 (1993), chapter 6, pp. 293 to 306, for example. Due to such concentric defect distribution, the single-crystal silicon substrate has concentric electrical characteristic distribution.
Non-patent Document 1: Fumio Shimura, “Semiconductor Silicon Crystal Technology”, Maruzen Publishing Co., Ltd published on September 30, Heisei 5 (1993), chapter 6, pp. 293 to 306.

### SUMMARY OF THE INVENTION

When a solar cell is formed by using a single-crystal silicon substrate having such concentric electrical characteristic distribution, the output of the solar cell decreases due to the existence of a portion having relatively poor electrical characteristics in the solar cell.

An object of an embodiment of the invention is to provide a solar cell, a solar cell module, and a method for manufacturing the solar cell which can suppress a decrease in output due to variation in electrical characteristics of a single-crystal silicon substrate.

A solar cell of a first aspect of the invention includes: a single-crystal silicon substrate having electrical characteristic distribution which is line symmetric with respect to a center line in a plan view and in which portions equidistant from the center line have an electrical characteristic substantially uniform in an extending direction of the center line in the plan view; a semiconductor junction formed by using the single-crystal silicon substrate; and an electrode.

A solar cell module of a second aspect of the invention includes solar cells electrically connected to one another in series, the solar cells each including: a single-crystal silicon substrate having electrical characteristic distribution which is line symmetric with respect to a center line in a plan view and in which portions equidistant from the center line have an electrical characteristic substantially uniform in an extending direction of the center line in the plan view; a semiconductor junction formed by using the single-crystal silicon substrate; and an electrode.

A method for manufacturing a solar cell of a third aspect of the invention includes the steps of: forming a single-crystal silicon ingot having concentric electrical characteristic distribution by crystal growth; slicing the single-crystal silicon ingot along a plane parallel to a growth direction of the single-crystal silicon ingot and thereby forming a single-crystal silicon substrate having electrical characteristic distribution which is line symmetric with respect to a center line and in which portions equidistant from the center line have an electrical characteristic substantially uniform in an extending direction of the center line; forming a semiconductor junction by using the single-crystal silicon substrate; and forming an electrode.

In the solar cell of the first aspect of the invention, the solar cell module of the second aspect, and the method for manufacturing a solar cell of the third aspect, the single-crystal silicon substrate having the electrical characteristic distribution described above is used. This can suppress variation in the electrical characteristics in the extending direction of the center line. Accordingly, the existence of a portion where the electrical characteristics are relatively poor in one solar cell can be suppressed by providing the electrode in the extending direction of the center line. Hence, a decrease in output of the solar cell can be suppressed.

### BRIEF DESCRIPTION OF THE DRAWINGS

FIG. 1 is a perspective view showing an overall structure of a solar cell module using solar cells of an embodiment of the invention.

FIG. 2 is a top view showing the solar cell module shown in FIG. 1.

FIG. 3 is a top view showing one of the solar cells of the embodiment which are shown in FIG. 1.

FIG. 4 is a cross-sectional view taken along line 100-100 of FIG. 3.

FIG. 5 is a cross-sectional view showing a single-crystal silicon ingot.

FIG. 6 is a perspective view showing a block obtained after dividing the single-crystal silicon ingot shown in FIG. 5.

FIG. 7 is a perspective view for explaining a step of forming single-crystal silicon substrates by slicing the block shown in FIG. 6 in a direction parallel to a growth direction of the ingot.

FIG. 8 is a plan view showing a single-crystal silicon substrates of an example and a comparative example which are used in a comparison experiment to verify effects of the embodiment are verified.

FIG. 9 is a plan view showing solar cells of an example and a comparative example which are used in the comparison experiment to verify the effects of the embodiment.

FIG. 10 is a view showing voltage-current characteristics of solar cells using single-crystal silicon substrates of example A1 and comparative example B1, respectively.

FIG. 11 is a view showing voltage-current characteristics of solar cells using single-crystal silicon substrates of example A2 and comparative example B2, respectively.

FIG. 12 is a view showing voltage-current characteristics of solar cells using single-crystal silicon substrates of example A3 and comparative example B3, respectively.

### DETAILED DESCRIPTION OF EMBODIMENTS

An embodiment is described below based on the drawings.

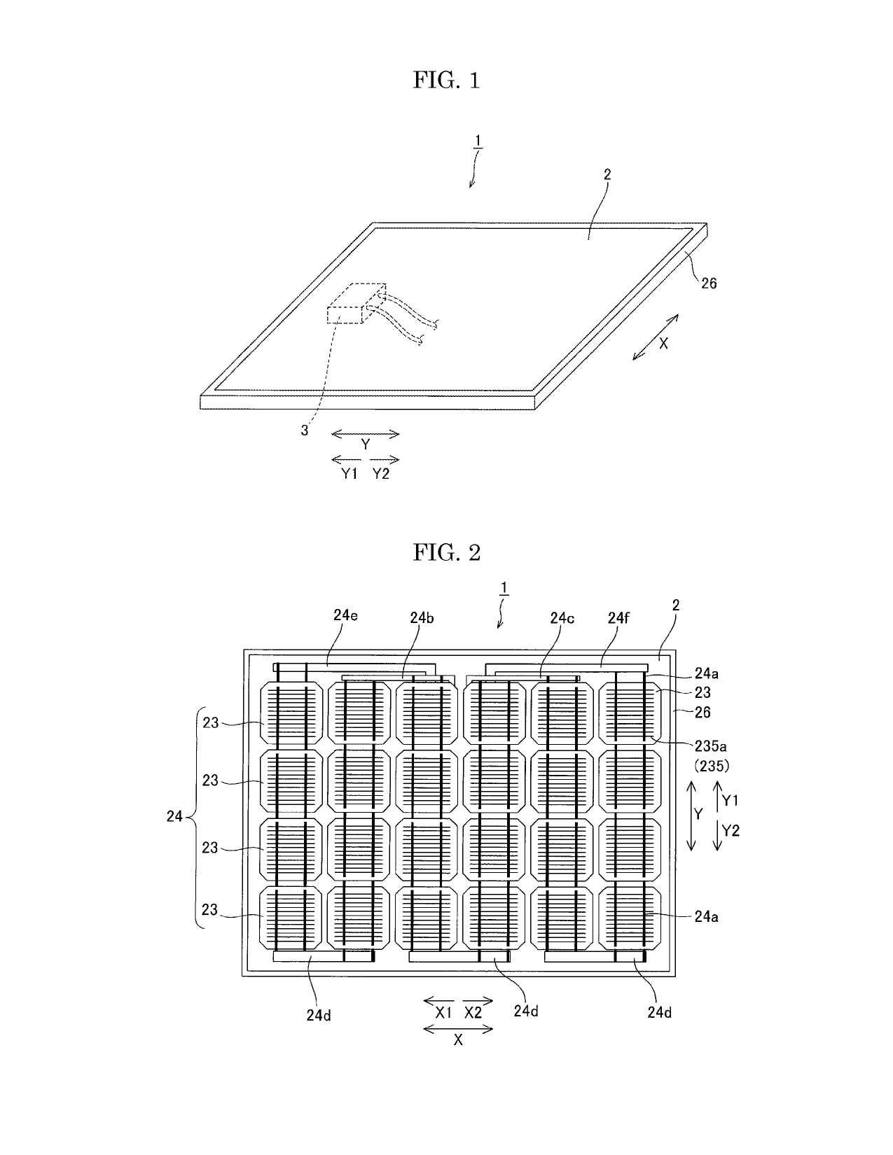

First, description is given of a structure of solar cell module 1 using solar cells 23 of the embodiment with reference to FIGS. 1 to 4.

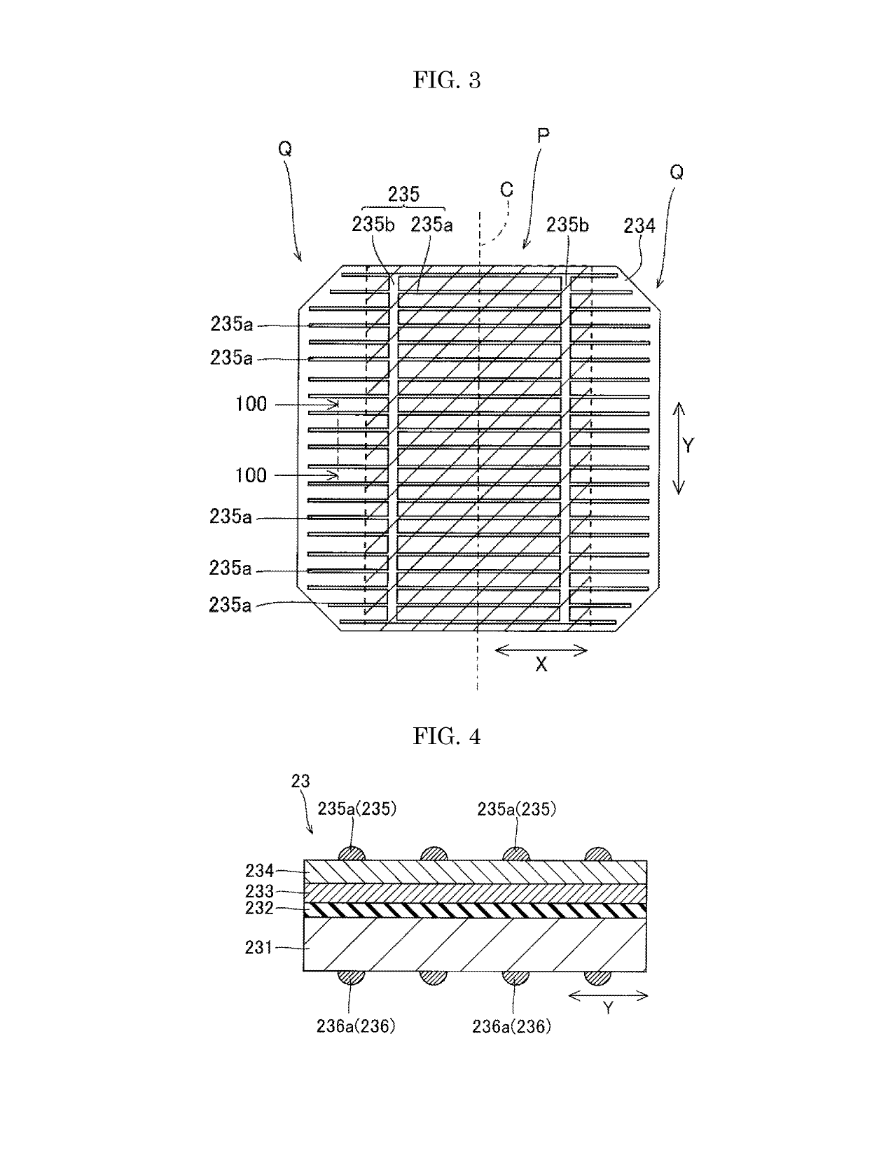

As shown in FIGS. 1 and 2, solar cell module 1 includes plate-shaped solar cell panel 2 and terminal box 3 (see FIG. 3) fixed to a back surface (surface opposite to a light receiving surface) of solar cell panel 2. Solar cell panel 2 includes: a front cover including transparent member made of tempered extra-clear glass or the like; a weather-resistant back cover including a resin film made of polyethylene terephthalate (PET) or the like; solar cell groups 24 each including solar cells 23 which are disposed between the front cover and the back cover and which are electrically connected to one another in series; a sealant provided between the front cover (back cover) and solar cells 23; and frame body 26 made of metal such as aluminum. Moreover, terminal box 3 is provided to collect electricity generated by solar cells 23 (solar cell groups 24) of solar cell panel 2. Terminal box 3 is fixed onto a surface of the back cover of solar cell panel 2 by being adhered thereto via adhesive.

A structure of a cross section taken along line 100-100 shown in FIG. 3 is as follows. As shown in FIG. 4, each solar cell 23 has: n-type single-crystal silicon substrate 231 having a main surface which is a (100) plane; substantially-intrinsic i-type amorphous silicon layer 232 formed on a top surface of n-type single-crystal silicon substrate 231; p-type amorphous silicon layer 233 formed on a top surface of i-type amorphous silicon layer 232; and transparent conductive film 234 formed on a top surface of p-type amorphous silicon layer 233 and made of a transparent conductive oxide. In the embodiment, n-type single-crystal silicon substrate 231, i-type amorphous silicon layer 232, and p-type amorphous silicon layer 233 form a semiconductor junction. Note that n-type single-crystal silicon substrate 231 is an example of “single-crystal silicon substrate of a first conductivity type” in the embodiment. Moreover, i-type amorphous silicon layer 232 is an example of “first amorphous semiconductor layer” in the embodiment. Furthermore, p-type amorphous silicon layer 233 is an example of “second amorphous semiconductor layer of a second conductivity type” in the embodiment.

In the embodiment, as shown in FIG. 3, n-type single-crystal silicon substrate 231 has electrical characteristic distribution which is line symmetric with respect to center line C in a plan view and in which portions equidistant from center line C in a direction (X direction) orthogonal to an extending direction (Y direction) of center line C have electric characteristics substantially uniform in the extending direction of center line C in the plan view. The electrical characteristics refer to characteristics, such for example as lifetime and resistivity, which vary depending on the existence of impurity and crystal defect occurring during manufacturing of a single-crystal silicon ingot. For example, as shown in FIG. 3, the electrical characteristics of a hatched (shaded) region (hereafter, referred to as high-level electrical characteristic region P) are better than those of regions not hatched (hereafter, referred to as low-level electrical characteristic regions Q) outside high-level electrical characteristic region P in the X direction. High-level electrical characteristic region P and low-level electrical characteristic regions Q are distributed line symmetric with respect to center line C while extending in the extending direction of center line C as described above. In n-type single-crystal silicon substrate 231, high-level electrical characteristic region P and low-level electrical characteristic regions Q extend from one end to the other end of n-type single-crystal silicon substrate 231 in the extending direction of center line C. Low-level electrical characteristic regions Q are arranged outside high-level electrical characteristic region P when viewed from center line C. In FIG. 3, for convenience of description, n-type single-crystal silicon substrate 231 is sectioned into two types of regions of the electrical characteristics which are high-level electrical characteristic region P having relatively good electrical characteristics and low-level electrical characteristic region Q having relatively poor electrical characteristics. However, this does not mean that the electrical characteristics in each of high-level electrical characteristic region P and low-level electrical characteristic regions Q are uniform. Actually, each of high-level electrical characteristic region P and low-level electrical characteristic regions Q has electrical characteristic distribution in which electrical characteristics vary in the direction (X direction) orthogonal to the extending direction of center line C and in which of portions equidistant from center line C in the direction (X direction) orthogonal to the extending direction (Y direction) of center line C have electrical characteristics substantially uniform in the extending direction of center line C.

Moreover, as shown in FIGS. 2, 3, and 4, electrode 235 is formed in a predetermined region, on atop surface of transparent conductive film 234. Electrode 235 includes: finger electrode portions 235a which are formed in parallel to each other at predetermined intervals to extend in the X direction; and bus bar electrode portions 235b which collect electric currents flowing though finger electrode portions 235a and which extend in the Y direction. In addition, as shown in FIG. 4, back electrode 236 is formed on a back surface of n-type single-crystal silicon substrate 231. Like electrode 235, back electrode 236 includes: finger electrode portions 236a which are formed in parallel to each other at predetermined intervals to extend in the X direction; and bus bar electrode portions (not illustrated) which collect electric currents flowing though finger electrode portions 236a and which extend in the Y direction. Bus bar electrode portions 235b of electrode 235 and the bus bar electrode portions (not illustrated) of back electrode 236 are formed to extend in the extending direction of center line C. Finger electrode portions 235a of electrode 235 and finger electrode portions 236a of back electrode 236 are formed to extend in a direction substantially orthogonal to the extending direction of center line C. Due to this, the portions equidistant, in the X direction, from any of bus bar electrode portions 235b of electrode 235 and the bus bar electrode portions (not illustrated) of back electrode 236 which extend along center line C have electrical characteristics substantially uniform in the extending direction (Y direction) of bus bar electrode portions 235b of electrode 235 and the bus bar electrode portions of back electrode 236.

In each solar cell 23 of the embodiment, output characteristics of a region from which one of the finger electrode portions (finger electrode portions 235a and 236a) collects electricity are substantially identical to output characteristics of each of regions from which the other finger electrode portions collect electricity. In other words, a configuration of each solar cell 23 of the embodiment is equivalent to a configuration in which electricity generating elements having identical output characteristics are connected in parallel to the bus bar electrode portions (bus bar electrode portions 235b of electrode 235 and the bus bar electrode portion 236b of back electrode 236), continuously in the Y direction.

Electrode 235 of one solar cell 23 out of neighboring solar cells 23 is electrically connected to back electrode 236 of other solar cell 23 via tab electrodes 24a including a solder-plated copper wire or the like. Tab electrodes 24a are connected onto bus bar electrode portions 235b of electrodes 235 and the bus bar electrode portions (not illustrated) of back electrodes 236. Multiple (four in the embodiment) solar cells 23 are connected in series in the Y direction by tab electrodes 24a and each solar cell group 24 is thereby formed.

As shown in FIG. 2, multiple (six in the embodiment) solar cell groups 24 are provided. Solar cell groups 24 are arranged in parallel to each other in the X direction. Assuming that a column at an end portion on a side of a direction of arrow X1 in FIG. 2 is a first column, solar cells 23 disposed in end portions of solar cell groups 24 of second and third columns on a side of a direction of arrow Y1 are electrically connected to each other by tab electrodes 24a and L-shaped connection member 24b. Solar cells 23 disposed in end portions of solar cell groups 24 of fourth and fifth columns on the side of the direction of arrow Y1 are electrically connected to each other by tab electrodes 24a and L-shaped connection member 24c. Solar cells 23 disposed in end portions of solar cell groups 24 of the first and second columns on a side of a direction of arrow Y2, solar cells 23 disposed in end portions of solar cell groups 24 of the third and fourth columns on the side of the direction of arrow Y2, and solar cells 23 disposed in end portions of solar cell groups 24 of the fifth and sixth columns on the side of the direction of arrow Y2 are electrically connected to each other by tab electrodes 24a and connection members 24d. Solar cell groups 24 are thus electrically connected to one another in series via connection members 24b, 24c, and 24d. L-shaped connection members 24e and 24f are connected respectively to solar cells 23 located at terminal ends (solar cells 23 located in the end portions of solar cell groups 24 of the first and sixth columns in the direction of arrow Y1) in solar cell groups 24 electrically connected in series. Moreover, connection members 24b, 24c, 24d, 24e, and 24f are each electrically connected to bus bar electrode portions 235b of electrode 235 or the bus bar electrode portions (not illustrated) of back electrode 236 in solar cell 23 located in the end portions of solar cell groups 24 in the Y direction, via tab electrodes 24a.

Furthermore, each of L-shaped connection members 24b, 24c, 24e, and 24f is lead out from solar cell panel 2 through a notch in the back cover. An end portion of each of connection members 24b, 24c, 24e, and 24f is electrically connected to a terminal block (not illustrated) in terminal box 3.

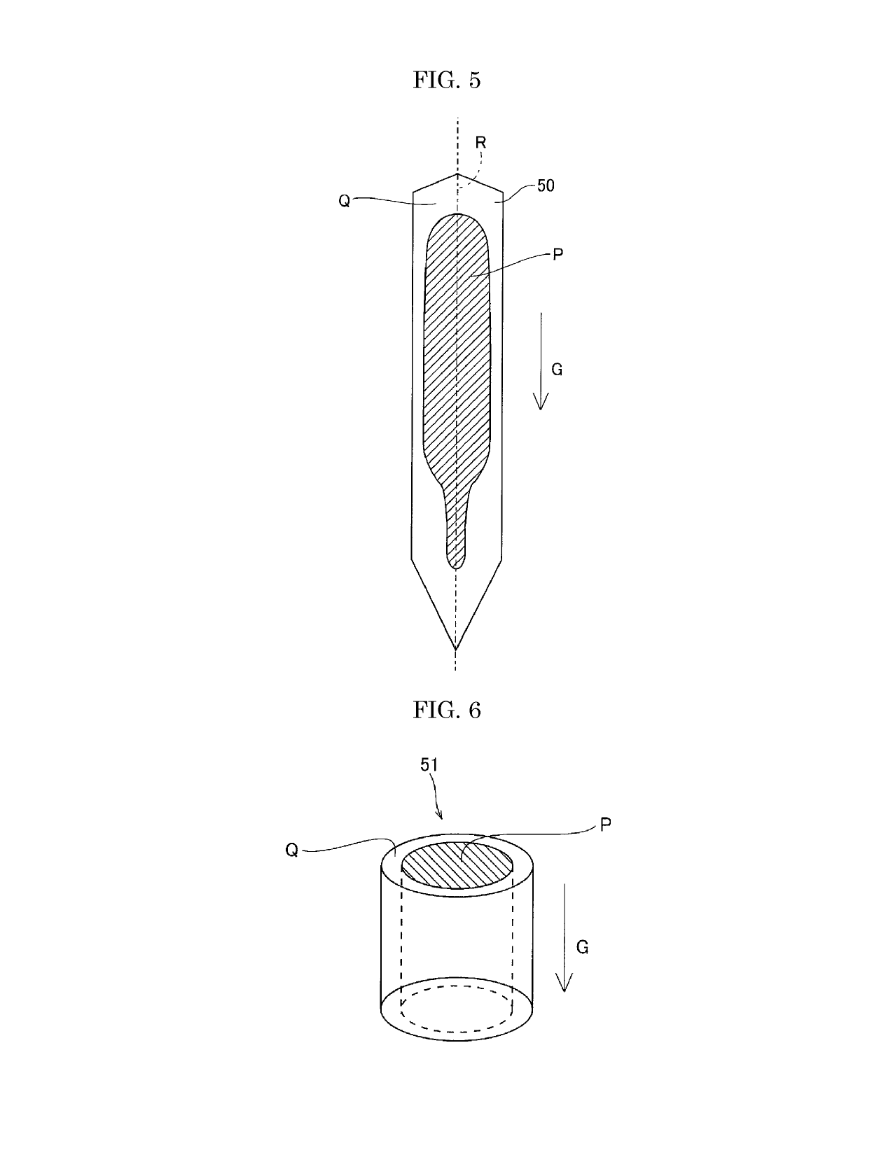

Next, description is given of a manufacturing process of solar cells 23 of the embodiment. First, as shown in FIG. 5, single-crystal silicon ingot 50 doped with an n-type impurity is produced by a predetermined method (for example, Czochralski method (Cz method) or the like). At this time, single-crystal silicon ingot 50 is produced by growing single-crystal silicon in such a way that a plane orthogonal to a growth direction of single-crystal silicon ingot 50 is the (100) plane. Generally, single-crystal silicon is grown while being rotated about rotation axis R. Accordingly, electrical characteristics of produced single-crystal silicon ingot 50 are distributed eccentrically about rotation axis R.

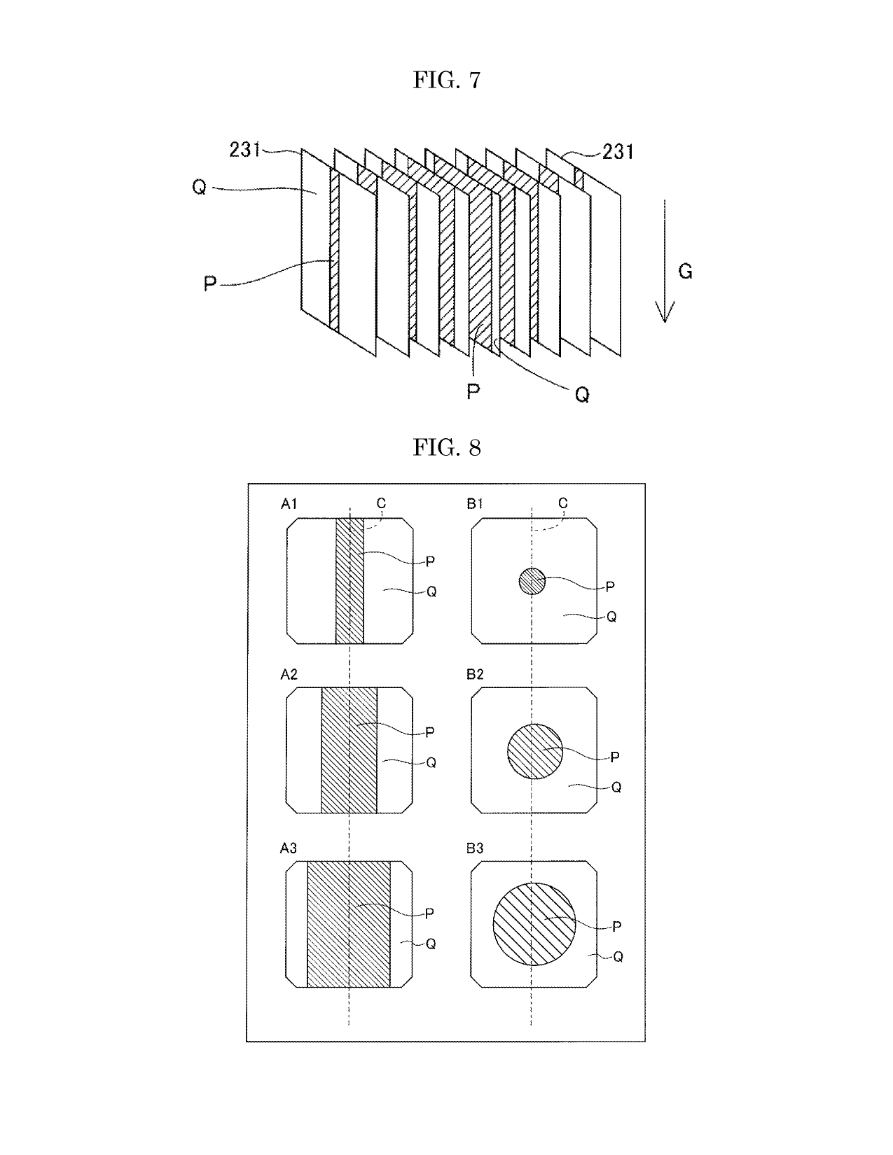

Next, as shown in FIG. 6, single-crystal silicon ingot 50 is sliced along planes orthogonal to the growth direction (direction of arrow G) and is thereby divided into blocks 51. Then, in the manufacturing process of the embodiment, each of columnar blocks 51 is shaped into a rectangular-solid shape. Thereafter, as shown in FIG. 7, block 51 is sliced along planes parallel to the direction of arrow G and n-type single-crystal silicon substrates 231 each having a predetermined thickness are thereby obtained. Each of n-type single-crystal silicon substrates 231 thus obtained has the electrical characteristic distribution which is line symmetric with respect to center line C extending in the direction of arrow G and in which the portions equidistant from center line C in a direction orthogonal to the extending direction of center line C have the electrical characteristics substantially uniform in the extending direction of center line C. Moreover, assume a case where, in single-crystal silicon ingot 50, a plane orthogonal to the growth direction (direction of arrow G) (<100> direction) is the (100) plane, and this single-crystal silicon ingot 50 is sliced along a plane parallel to the growth direction. In this case also, a main surface of each of obtained n-type single-crystal silicon substrates 231 is the (100) plane.

Next, impurities are removed by cleaning each n-type single-crystal silicon substrate 231 and a texture structure (uneven shape) is formed by etching. Subsequently, i-type amorphous silicon layer 232 and p-type amorphous silicon layer 233 are sequentially deposited on n-type single-crystal silicon substrate 231 by using a CVD method. The semiconductor junction is thereby formed. Note that B, Al, Ga, and In which are group 3 elements can be given as an example of a p-type dopant used to form p-type amorphous silicon layer 233. p-type amorphous silicon layer 233 can be formed by mixing a compound gas including at least one of p-type dopants described above into a material gas such as SiH₄ (silane) gas, during the formation of p-type amorphous silicon layer 233.

Next, transparent conductive film 234 made of indium oxide film is formed on p-type amorphous silicon layer 233 by using a PVD method. Then, Ag paste obtained by kneading silver (Ag) fine powder together with the epoxy resin is applied onto predetermined regions of the top surface of transparent conductive film 234 by using a screen printing method. At this time, the Ag paste is applied in such a way that, as shown in FIG. 3, bus bar electrode portions 235b extend in the extending direction of center line C and finger electrode portions 235a extend in the direction orthogonal to the extending direction of center line C. Thereafter, the Ag paste is hardened by being baked at about 200° C. for about 80 minutes. Thus, there is formed electrode 235 including: finger electrode portions 235a which are formed in parallel to each other at predetermined intervals to extend in the X direction; and bus bar electrode portions 235b which collect electric currents flowing though finger electrode portions 235a and which extend in the Y direction.

Then, the Ag paste obtained by kneading the silver (Ag) fine powder together with the epoxy resin is applied onto the back surface of n-type single-crystal silicon substrate 231 by using the screen printing method. At this time, like in the formation of electrode 235, the Ag paste is applied in such a way that the bus bar electrode portions (not illustrated) extend in the extending direction of center line C and finger electrode portions 236a extend in the direction orthogonal to the extending direction of center line C. Thereafter, the Ag paste is hardened by being baked at about 200° C. for about 80 minutes. Thus, there is formed back electrode 236 including: finger electrode portions 236a which are formed in parallel to each other at predetermined intervals to extend in the X direction; and the bus bar electrode portions (not illustrated) which collect electric currents flowing though finger electrode portions 236a and which extend in the Y direction. Solar cells 23 of the embodiment are formed as described above.

Next, description is given of a manufacturing process of solar cell module 1 using solar cells 23 of the embodiment with reference to FIGS. 1 and 2. First, end portions of tab electrodes 24a made of copper foil on one side are connected respectively to bus bar electrode portions 235b of electrodes 235 of solar cells 23 formed as described above. Then, end portions of tab electrodes 24a on the other side are connected respectively to bus bar electrode portions (not illustrated) of the back electrodes 236 of neighboring solar cells 23. As shown in FIGS. 1 and 2, solar cells 23 are thus connected in series. At this time, it is desirable that a combination of solar cells 23 using n-type single-crystal silicon substrates 231 having a small difference in electrical characteristics therebetween (solar cells 23 having a small difference in output therebetween) be selected as solar cells 23 connected in series In other words, it is desirable to select a combination of solar cells 23 using n-type single-crystal silicon substrates 231 having substantially identical electrical characteristics (solar cells 23 having substantially the same output).

Next, an EVA sheet eventually serving as the sealant, solar cells 23 connected by tab electrodes 24a, and another EVA sheet eventually serving as the sealant are disposed between the front cover made of glass and the back cover, in this order from the front cover side. Thereafter, thus-disposed parts are subjected to a vacuum laminating process while being heated and solar cell module 1 shown in FIG. 1 is thereby formed.

In the embodiment, variation in electrical characteristics in the extending direction of center line C can be suppressed by using n-type single-crystal silicon substrate 231 having electrical characteristic distribution which is line symmetric with respect to center line C in the plan view and in which portions equidistant from center line C have electrical characteristics substantially uniform in the extending direction of center line C, as described above. Accordingly, the existence of a portion where the electrical characteristics are relatively poor in one solar cell 23 can be suppressed by providing electrode 235 and back electrode 236 in the extending direction of center line C. Hence, a decrease in output of solar cell 23 can be suppressed.

In the embodiment, as described above, bus bar electrode portions 235b of electrode 235 and the bus bar electrode portions (not illustrated) of back electrode 236 are provided to extend, in the plan view, in the extending direction of the center line C in which the electrical characteristics are substantially uniform, and finger electrode portions 235a and 236a are provided to extend, in the plan view, in the direction intersecting the extending direction of center line C. Due to this, the portions equidistant, in the X direction, from any of bus bar electrode portions 235b of electrode 235 and the bus bar electrode portions (not illustrated) of back electrode 236 which extend along center line C have the electrical characteristics substantially uniform in the extending direction (direction Y) of bus bar electrode portions 235b of electrode 235 and the bus bar electrode portions of back electrode 236. Accordingly, collection of electricity can be performed with bus bar electrode portions 235b of electrode 235 and the bus bar electrode portions (not illustrated) of back electrode 236, in a direction in which the electrical characteristics are uniform. This can suppress a decrease in output of solar cell 23 which is caused by the existence of a portion where the electrical characteristics are relatively poor in solar cell 23.

In the embodiment, as described above, multiple finger electrode portions 235a and 236a are provided and the output characteristics of the regions respectively from which finger electrode portions 235a and 236a collect electricity are substantially identical to each other. This can suppress a decrease in output of solar cell 23 which is caused by the existence of a portion where the output characteristics are relatively poor in solar cell 23.

In the embodiment, the main surface of n-type single-crystal silicon substrate 231 is the (100) plane as described above. Accordingly, solar cell 23 can be manufactured by using n-type single-crystal silicon substrate 231 having the (100) plane as the main surface which has been conventionally used, and at the same time a decrease in output of solar cell 23 is suppressed.

In the embodiment, n-type single-crystal silicon substrate 231 whose electrical characteristics from one end to the other end in the extending direction of center line C are substantially uniform is used as described above. This can further suppress a decrease in output of solar cell 23.

Additionally, in the embodiment, high-level electrical characteristic region P and low-level electrical characteristic regions Q are substantially line symmetric with respect to center line C and low-level electrical characteristic regions Q are arranged outside high-level electrical characteristic region P when viewed from center line C as described above. A decrease in output of solar cell 23 which is caused by the existence of a portion where the electrical characteristics are relatively poor in solar cell 23 can be easily suppressed by such an arrangement of high-level electrical characteristic region P and low-level electrical characteristic regions Q, when electricity is collected in the extending direction (Y direction) of center line C.

In the embodiment, the electrical characteristics of n-type single-crystal silicon substrate 231 of neighboring ones of solar cells 23 are substantially identical to each other as described above. Accordingly, a decrease in output of entire solar cell module 1 formed by electrically connecting solar cells 23 in series can be easily suppressed.

In the embodiment, single-crystal silicon ingot 50 is sliced along the planes parallel to the growth direction (direction of arrow G) of single-crystal silicon ingot 50 and n-type single-crystal silicon substrates 231 can be thereby easily formed, n-type single-crystal silicon substrates 231 each having the electrical characteristic distribution which is line symmetric to center line C and in which the portions equidistant from center line C have the electrical characteristic substantially uniform in the extending direction of center line C.

Next, description is given of a comparison experiment to verify effects of the embodiment with reference to FIGS. 8 to 12.

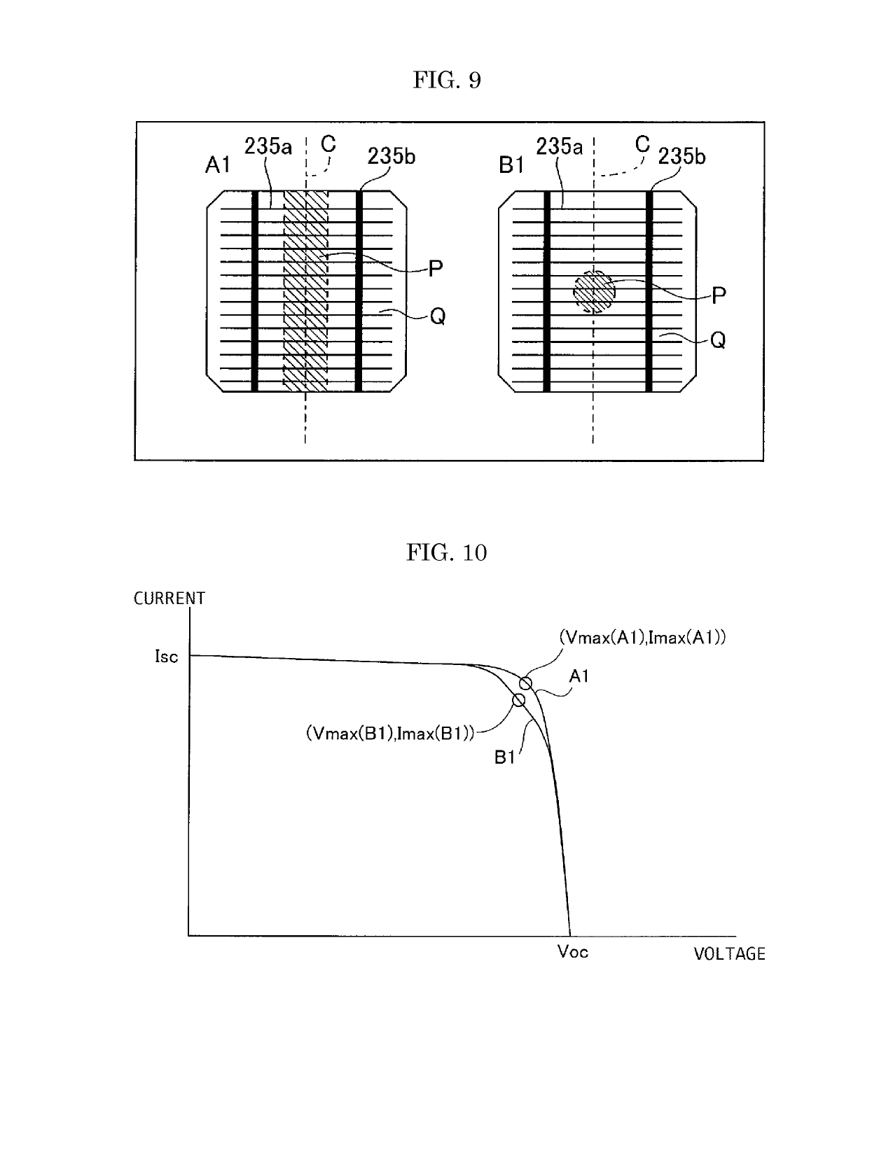

In the comparison experiment, an output of a solar cell manufactured by using a single-crystal silicon substrate of an example obtained by the manufacturing method of the embodiment described above is compared with an output of a solar cell manufactured by using a single-crystal silicon substrate of a comparative example obtained by a conventional manufacturing method. Specifically, single-crystal silicon ingot 50 like one shown in FIG. 5 is sliced along planes parallel to rotation axis R to form single-crystal silicon substrates of A1, A2, and A3 in which regions of electrical characteristics are different as shown in FIG. 8. Moreover, single-crystal silicon ingot 50 is sliced along planes perpendicular to rotation axis R to form single-crystal silicon substrates of B1, B2, and B3 in which regions of electrical characteristics are different as shown in FIG. 8. Then, as shown in FIG. 9, solar cells A1 and B1 are fabricated by using single-crystal silicon substrates A1 and B1, respectively, in a process similar to that in the embodiment described above. Similarly, solar cells A2, A3, B2, and B3 are fabricated by using single-crystal silicon substrates A2, A3, B2 and B3, respectively.

Then, voltage-current characteristics of solar cells A1 to A3 are compared respectively with voltage-current characteristics of solar cells B1 to B3. FIGS. 10, 11, and 12 respectively show an experiment result of solar cell A1 and solar cell B1, an experiment result of solar cell A2 and solar cell B2, and an experiment result of solar cell A3 and solar cell B3.

As shown in FIG. 10, it is found that short-circuit current Isc and open-circuit voltage Voc in solar cell A1 of the example are the same as those in solar cell B1 of the comparative example while maximum power (Vmax(A1)×Imax(A1)) of solar cell A1 is lager than maximum power (Vmax(B1)×Imax(B1)) of solar cell B1. In other words, it is found that solar cell A1 of the example is improved in fill factor F.F. compared to solar cell B1 of the comparative example.

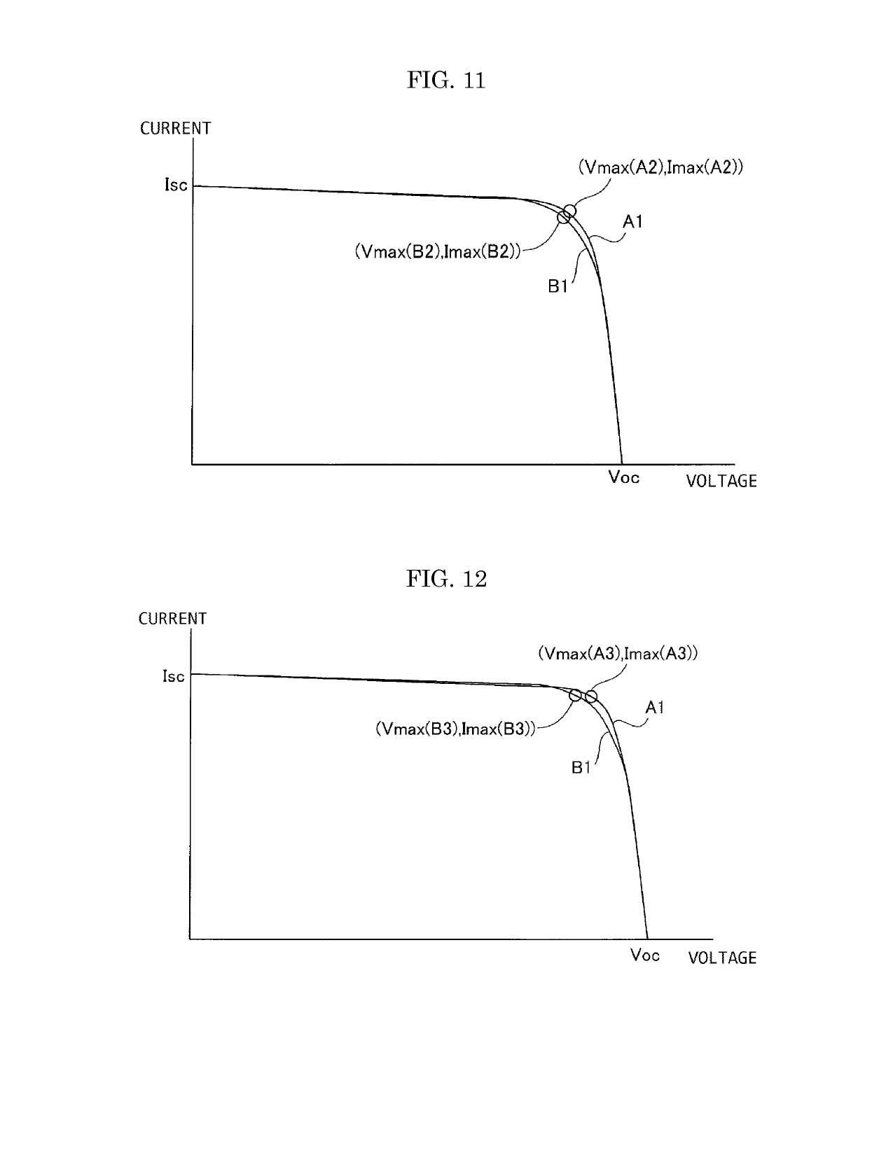

Moreover, as shown in FIG. 11, it is found that short-circuit current Isc and open-circuit voltage Voc in solar cell A2 of the example are the same as those in solar cell B2 of the comparative example while maximum power (Vmax(A2)×Imax(A2)) of solar cell A2 is lager than maximum power (Vmax(B2)×Imax(B2)) of solar cell B2. In other words, it is found that solar cell A2 of the example is improved in fill factor F.F. compared to solar cell B2 of the comparative example.

Furthermore, as shown in FIG. 12, it is found that short-circuit current Isc and open-circuit voltage Voc in solar cell A3 of the example are the same as those in solar cell B3 of the comparative example while maximum power (Vmax(A3)×Imax(A3)) of solar cell A3 is lager than maximum power (Vmax(B3)×Imax(B3)) of solar cell B3. In other words, it is found that solar cell A3 of the example is improved in fill factor F.F. compared to solar cell B3 of the comparative example.

The following reasons are conceivable as reasons for these results. Specifically, in each of solar cells A1 to A3 of the example, the single-crystal silicon substrate in which the portions equidistant from center line C have the electrical characteristics substantially uniform in the extending direction of center line C is used and the electrical characteristics are thus uniform in an extending direction of the bus bar electrode portions. Accordingly, there is no variation in characteristics along the bus bar electrode portions and an output of a portion with good characteristics is thus not hindered by an output of a portion with poor characteristics. Hence, loss (decrease) of output is suppressed. On the other hand, in each of solar cells B1 to B3 of the comparative example, the single-crystal silicon substrate in which the electrical characteristics are concentrically distributed is used. Accordingly, there is variation in electrical characteristics in the extending direction of bus bar electrode portions. Hence, an output of a portion with good characteristics is hindered by an output of a portion with poor characteristics and the output of the solar cell thereby decreases. Accordingly, it is assumed that solar cells A1 to A3 of the examples are improved in output (fill factor) compared to solar cells B1 to B3 of the comparative examples.

It should be understood that the embodiment disclosed herein is exemplary in all points and does not limit the embodiment. The scope of the embodiment is defined not by the descriptions of the embodiment but by claims and includes equivalents of claims and all modifications within the scope of claims.

For example, in the embodiment described above, description is given of the example using the single-crystal silicon substrate whose main surface is the (100) plane. However, the embodiment is not limited to this and may use a single-crystal silicon substrate using a different plane as a main surface.

In the embodiment described above, silicon (Si) is used as the semiconductor material. However, the embodiment is not limited to this and may use any of semiconductors including SiGe, SiGeC, SiC, SiN, SiGeN, SiSn, SiSnN, SiSnO, SiO, Ge, GeC, and GeN. In this case, these semiconductors may be crystalline or any one of amorphous and microcrystallite which include at least one of hydrogen and fluorine.

In the embodiment described above, description is given of the example in which the extending direction (X direction) of finger electrode portions 235a and 236a is substantially orthogonal to the extending direction (Y direction) of bus bar electrode portions 235b. However, the embodiment is not limited to this. Specifically, the extending direction of finger electrode portions 235a and 236a may be a direction obliquely intersecting the extending direction (Y direction) of bus bar electrode portions 235b.

The semiconductor junction of the embodiment can be also formed by thermally diffusing a dopant into the single-crystal silicon substrate. Moreover, the embodiment can be applied also to a back-junction-type solar cell.

1. A solar cell comprising:
a single-crystal silicon substrate having electrical characteristic distribution that is line symmetric with respect to a center line in a plan view and in which portions equidistant from the center line have an electrical characteristic substantially uniform in an extending direction of the center line in the plan view;
a semiconductor junction formed by using the single-crystal silicon substrate; and
an electrode.

2. The solar cell according to claim 1, wherein the electrode includes: a bus bar electrode portion extending, in the plan view, in the extending direction of the center line along which the electrical characteristic is substantially uniform; and a finger electrode portion extending in a direction intersecting the extending direction of the center line in the plan view.

3. The solar cell according to claim 2, wherein
a plurality of the finger electrode portions are provided, and
output characteristics of regions respectively from which the finger electrode portions collect electricity are substantially equivalent to each other.

4. The solar cell according to claim 1, wherein a main surface of the single-crystal silicon substrate is a (100) plane.

5. The solar cell according to claim 1, wherein the electrical characteristic is substantially uniform from one end to another end of the single-crystal silicon substrate in the extending direction of the center line.

6. The solar cell according to claim 1, wherein the electrical characteristic includes lifetime and resistivity.

7. The solar cell according to claim 1, wherein
the single-crystal silicon substrate includes a high-level electrical characteristic region in which the electrical characteristics are relatively good and low-level electrical characteristic regions in which the electrical characteristics are relatively poor,
the high-level electrical characteristic region and the low-level electrical characteristic regions are both configured to be substantially line symmetric with respect to the center line, and
the low-level electrical characteristic regions are arranged outside the high-level electrical characteristic region when viewed from the center line.

8. The solar cell according to claim 1, wherein
the single-crystal silicon substrate includes a single-crystal silicon substrate of a first conductivity type, and
the semiconductor junction includes:
the single-crystal silicon substrate of the first conductivity type;
a substantially-intrinsic first amorphous semiconductor layer which is formed on the single-crystal silicon substrate of the first conductivity type; and
a second amorphous semiconductor layer of a second conductivity type which is formed on the first amorphous semiconductor layer.

9. A solar cell module comprising solar cells electrically connected to one another in series, the solar cells each including:
a single-crystal silicon substrate having electrical characteristic distribution which is line symmetric with respect to a center line in a plan view and in which portions equidistant from the center line have an electrical characteristic substantially uniform in an extending direction of the center line in the plan view;
a semiconductor junction formed by using the single-crystal silicon substrate; and
an electrode.

10. The solar cell module according to claim 9, wherein the electrical characteristics of the single-crystal silicon substrates of neighboring solar cells among the solar cells are substantially equivalent to each other.

11. The solar cell module according to claim 9, wherein the electrode of each of the solar cells includes: a bus bar electrode portion extending, in the plan view, in the extending direction of the center line along which the electrical characteristic is substantially uniform; and a finger electrode portion extending in a direction intersecting the extending direction of the center line in the plan view.

12. The solar cell module according to claim 11, wherein
a plurality of the finger electrode portions are provided in each of the solar cells, and
output characteristics of regions respectively from which the finger electrode portions collect electricity are substantially equivalent to each other.

13. The solar cell module according to claim 9, wherein a main surface of the single-crystal silicon substrate of each of the solar cells is a (100) plane.

14. The solar cell module according to claim 9, wherein the electrical characteristics of the single-crystal silicon substrate of each of the solar cells are substantially uniform from one end to another end of the single-crystal silicon substrate in the extending direction of the center line.

15. The solar cell module according to claim 9, wherein the electrical characteristic of the single-crystal silicon substrate of each of the solar cells includes lifetime and resistivity.

16. The solar cell module according to claim 9, wherein
the single-crystal silicon substrate of each of the solar cells includes a high-level electrical characteristic region in which the electrical characteristics are relatively good and low-level electrical characteristic regions in which the electrical characteristics are relatively poor,
the high-level electrical characteristic region and the low-level electrical characteristic regions are both configured to be substantially line symmetric with respect to the center line, and
the low-level electrical characteristic regions are arranged outside the high-level electrical characteristic region when viewed from the center line.

17. The solar cell module according to claim 9, wherein
the single-crystal silicon substrate of each of the solar cells includes a single-crystal silicon substrate of a first conductivity type, and
the semiconductor junction of each of the solar cells includes:
the single-crystal silicon substrate of the first conductivity type;
a substantially-intrinsic first amorphous semiconductor layer which is formed on the single-crystal silicon substrate of the first conductivity type; and
a second amorphous semiconductor layer of a second conductivity type which is formed on the first amorphous semiconductor layer.

18. A method for manufacturing a solar cell comprising the steps of:
forming a single-crystal silicon ingot having concentric electrical characteristic distribution by crystal growth;
slicing the single-crystal silicon ingot along a plane parallel to a growth direction of the single-crystal silicon ingot and thereby forming a single-crystal silicon substrate having electrical characteristic distribution which is line symmetric with respect to a center line and in which portions equidistant from the center line have an electrical characteristic substantially uniform in an extending direction of the center line;
forming a semiconductor junction by using the single-crystal silicon substrate; and
forming an electrode.

19. The method for manufacturing a solar cell according to claim 18, wherein the step of forming the electrode includes a step of forming: a bus bar electrode portion extending, in a plan view, in the extending direction of the center line along which the electrical characteristic is substantially uniform; and a finger electrode portion extending in a direction intersecting the extending direction of the center line in the plan view.

20. The method for manufacturing a solar cell according to claim 18, wherein the step of forming the single-crystal silicon substrate includes a step of forming the single-crystal silicon substrate in such a way that a main surface of the single-crystal silicon substrate is a (100) plane.
